(19) United States
(12) Patent Application Publication
(10) Pub. No.: US 2026/0064908 A1
(43) Pub. Date: Mar. 5, 2026

(54) SIMULATED SENSOR READING GENERATION FOR SENSOR

(71) Applicant: Avathon Inc., Austin, TX (US)

(72) Inventors: Akhilesh Jain, Austin, TX (US); Amanda Cox, Austin, TX (US)

(21) Appl. No.: 19/310,495

(22) Filed: Aug. 26, 2025

Related U.S. Application Data
(60) Provisional application No. 63/687,918, filed on Aug. 28, 2024.

(51) Int. Cl. G06F 30/20

(52) U.S. Cl. CPC G06F 30/20

(57) ABSTRACT

A system includes an interface configured to receive first sensor data from multiple first sensors associated with a monitored system and also includes one or more processors. The one or more processors are configured to provide first input data to a plurality of regression models of a first virtual sensor corresponding to a particular sensor of the monitored system. The first input data is based on the first sensor data. The one or more processors are configured to obtain, from the plurality of regression models, output data based on the input data. The output data from each regression model of the plurality of regression models represents an estimated sensor reading of the particular sensor. The one or more processors are also configured to determine a simulated sensor reading for the particular sensor based on the output data, determine a confidence estimate associated with the simulated sensor reading, or both.

### CROSS-REFERENCE TO RELATED APPLICATION

The present disclosure claims priority from U.S. Provisional Patent Application No. 63/687,918 filed Aug. 28, 2024, the entire content of which is incorporated by reference herein in its entirety.

### FIELD

The present disclosure is generally related to generation of simulated sensor readings for one or more sensors.

### BACKGROUND

Sensors are used to provide sensor data associated with conditions of a monitored system. The sensor data for the conditions may be converted to sensor readings (e.g., temperature, pressure, flow rate, etc.) and control devices may control operating conditions of the monitored system based on the sensor readings. For example, temperature sensors, pressure sensors, and other types of sensors are used to monitor downhole well conditions of oil wells. Sensor data from one or more of the sensors is converted to sensor readings, which may be used to determine control inputs (e.g., control inputs for control valves, pumps, heaters, coolers, etc.) to control the monitored system. Failure of such sensors may necessitate shut down of the monitored system or conservative operation of the monitored system to maintain operational safety.

For some failed sensors, the sensors are accessible, replacements are readily available, and the sensors are easily replaced. For other failed sensors, the sensors are not accessible (e.g., sensors on unmanned spacecraft); the sensors are difficult to access due to environmental factors (e.g., sensors in subsea wells, presence of hazardous materials, etc.); the sensors are not accessible during operation of the monitored system due to one or more operating conditions of the monitored system (e.g., high temperatures and/or pressures, etc.), the sensors are expensive to replace due to parts, labor, downtime, and other factors; or combinations thereof.

### SUMMARY

The present disclosure describes systems and methods to generate simulated sensor readings for one or more sensors of a monitored system based on sensor readings determined from sensor data of operational sensors of the monitored system. The one or more sensors may be failed sensors or particular operational sensors. When the one or more sensors are particular operational sensors, the simulated sensor readings may be compared to actual sensor readings produced from sensor data provided by the particular operational sensors to determine accuracy associated with one or more virtual sensors corresponding to the particular operational sensors.

In some aspects, a system includes an interface configured to receive first sensor data from multiple first sensors associated with a monitored system. The system also includes one or more processors. The one or more processors are configured to provide first input data to a plurality of regression models (e.g., regressors) of a first virtual sensor corresponding to a particular sensor of the monitored system. The first input data is based on the first sensor data. The one or more processors are configured to obtain, from the plurality of regression models, output data based on the input data. The output data from each regression model of the plurality of regression models represents an estimated sensor reading of the particular sensor. The one or more processors are also configured to determine a simulated sensor reading for the particular sensor based on the output data.

In some aspects, a method includes generating, by one or more processors, input data from first sensor data. The first sensor data from multiple sensors is associated with a monitored system. The method includes providing, by the one or more processors, the input data to a plurality of regression models of a first virtual sensor corresponding to a particular sensor of the monitored system. The method includes obtaining, by the one or more processors from the plurality of regression models, output data based on the input data. The output data from each regression model of the plurality of regression models represents an estimated sensor reading of the particular sensor. The method also includes determining, by the one or more processors, a simulated sensor reading for the particular sensor based on the output data.

In some aspects, a non-transitory computer-readable storage medium comprises instructions that are executable by one or more processors to cause the one or more processors to generate input data from first sensor data. The first sensor data is from multiple first sensors associated with a monitored system. The instructions cause the one or more processors to provide the input data to a plurality of regression models of a first virtual sensor corresponding to a particular sensor of the monitored system. The instructions cause the one or more processors to obtain, from the plurality of regression models, output data based on the input data. The output data from each regression model of the plurality of regression models represents an estimated sensor reading of the particular sensor. The instructions also cause the one or more processors to determine a representative simulated sensor reading for the particular sensor based on the output data.

### BRIEF DESCRIPTION OF THE DRAWINGS

FIG. 1 is a diagram illustrating particular aspects of a system to generate a simulated sensor reading for a particular sensor of a monitored system based on sensor readings of other sensors of the monitored system.

FIG. 2 is a flow chart of an example of a method of generating a simulated sensor reading for a particular sensor of a monitored system based on sensor readings of other sensors of the monitored system.

FIG. 3 is a flow chart of an example of a method of generating a virtual sensor for a particular sensor of a monitored system.

FIG. 4 illustrates an example of a computer system configured to generate virtual sensors, to use virtual sensors to generate simulated sensor readings for one or more corresponding sensors of a monitored system, or both, in accordance with some aspects of the present disclosure.

### DETAILED DESCRIPTION

The present disclosure describes systems and methods to generate simulated sensor readings using a virtual sensor for a particular sensor of a monitored system. The simulated sensor readings from the virtual sensor may be used in place of sensor readings determined from sensor data for the particular sensor when sensor data from the particular sensor is not reliable (e.g., is erratic), when the particular sensor has failed and is not generating sensor data, or combinations thereof. The simulated sensor data is generated by one or more virtual sensors. The one or more virtual sensors are trained with historical sensor data from the monitored system. The generated simulated sensor readings are based on recent and real-time values of operational sensors of the monitored system. The systems and methods also generate confidence estimates for the simulated sensor readings. The confidence estimates may be used to assess risks associated with continued operation of the monitored system.

One or more virtual sensors corresponding to a particular sensor may be developed. A virtual sensor corresponding to a sensor may include a single ensemble of regression models used to generate simulated sensor readings for a monitored system, or a plurality of virtual sensors corresponding to a sensor may be developed, where each virtual sensor is associated with a different regime of the monitored system. For example, a virtual sensor may include a first ensemble of regression models used to generate simulated sensor readings corresponding to a startup regime of the monitored system, and the virtual sensor may include a second ensemble of regression models used to generate simulated sensor readings for operation of the monitored system after the startup regime. The virtual sensor may also include one or more additional ensembles of regression models used to generate simulated sensor data for other regimes associated with the monitored system.

Advantageously, virtual sensors can serve as cost-effective replacements for physical sensors that are prone to failure and the virtual sensors effectively extend the life of existing sensors. For sensors that can be replaced, the use of virtual sensors advantageously enables continued use of the monitored system until one or more failed sensors can be replaced without a need for conservative operation of the monitored system before replacement of the one or more to ensure operational safety. For sensors that cannot be replaced, the use of virtual sensors advantageously extends the useful operational lifetime of the monitored system.

Advantageously, a virtual sensor requires no modification of the monitored system and virtual sensors can be developed for any sensor of a plurality of sensors used to monitor the monitored system. Advantageously, a virtual sensor can provide accurate simulated sensor readings (e.g., within 10% or better of sensor readings provided by operational sensors) for a time period (e.g., 1 month, 3 months, 6 months, or some other time period). The accuracy of sensor data provided by a virtual sensor can be significantly better than estimates of sensor data generated using physical models of the monitored system, which may have low accuracy (e.g., provide values that are more than 30% off from values provided by operational sensors).

Two or more virtual sensors can be utilized to provide accurate simulated sensor readings for a monitored system when multiple physical sensors, up to a threshold percentage (e.g., 50%, 40%, 30% or some other percent) of the sensors of the monitored system are unreliable or failed sensors. When multiple virtual sensors are generating simulated sensor readings, comparisons of sensor readings from actual sensor data from one or more verification data sets generated from recent data of the monitored system when the physical sensors corresponding to the virtual sensors were operational, may be compared to simulated sensor readings generated using the multiple virtual sensors to check that accuracy of the simulated sensor readings for the multiple virtual sensors are within acceptable limits (e.g., within 10% or better) of sensor readings determined from the actual data. If the accuracy of the simulated sensor readings is acceptable, the monitored system may continue to be operated. If the accuracy of the simulated sensor readings is not acceptable, the system may be operated conservatively or may be shut down.

For example, a monitored system having 10 sensors is operated and data from the 10 sensors is saved as historical sensor data. When sufficient historical sensor data is available (e.g., after 6 months, 1 year, 2 years, or some other time period), virtual sensors for each of the 10 sensors are generated based on training data sets (e.g., a training data set for each regression model of the ensemble model generated at random from the historical sensor data) and a verification data set generated from the historical data. At a first time, a first sensor of the 10 sensors fails. A corresponding first virtual sensor is used to generate simulated sensor data for the first sensor based on sensor data from the 9 remaining operational sensors. At a second time, a second sensor of the remaining 9 operational sensors fails. Virtual sensors corresponding to the first sensor and the second sensor are used to generate simulated sensor readings for the first sensor and the second sensor using sensor data from the 8 remaining operation sensors.

Techniques disclosed herein facilitate generation of simulated sensor readings for one or more sensors associated with a monitored system and confidence estimates for the simulated sensor readings. The simulated sensor readings and the confidence estimates can be generated for a failed sensor or for an operational sensor. When the simulated sensor readings are generated for an operational sensor, the simulated sensor readings may be used to determine accuracy of the simulated sensor readings by comparing the simulated sensor readings with sensor readings generated based on sensor data received from the operational sensor.

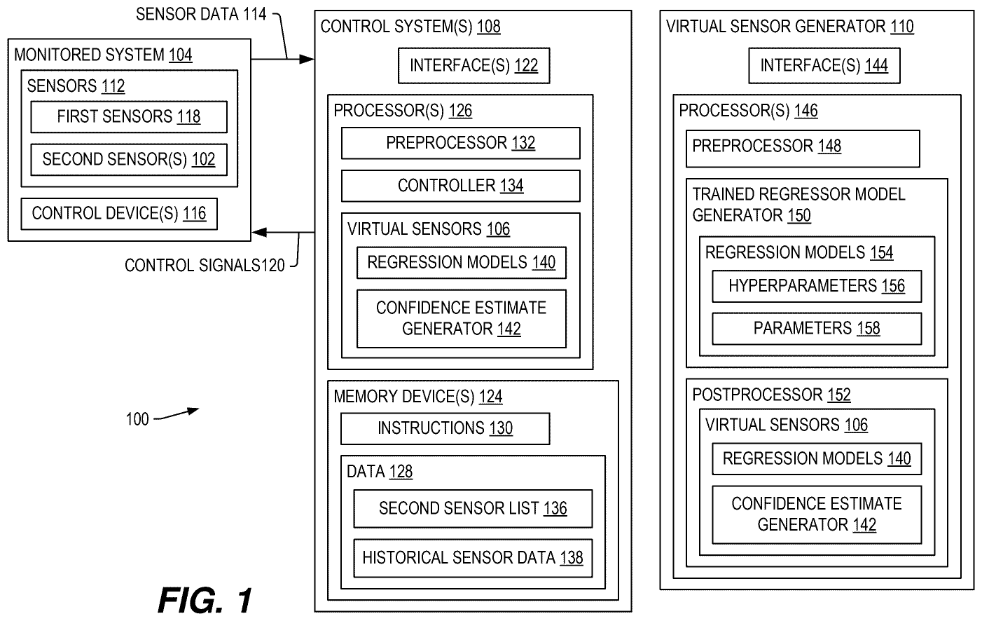

Particular aspects of the present disclosure are described below with reference to the drawings. In the description, common features are designated by common reference numbers throughout the drawings. As used herein, various terminology is used for the purpose of describing particular implementations only and is not intended to be limiting. For example, the singular forms “a,” “an,” and “the” are intended to include the plural forms as well, unless the context clearly indicates otherwise. Further, some features described herein are singular in some implementations and plural in other implementations. To illustrate, FIG. 1 depicts a system 100 including one or more processors (“processor(s)” 126 of FIG. 1), which indicates that in some implementations the system 100 includes a single processor 126 and in other implementations the system 100 includes multiple processors 126. For ease of reference herein, such features are generally introduced as “one or more” features and are subsequently referred to in the singular or optional plural (as indicated by “(s)”) unless aspects related to multiple of the features are being described.

As used herein, an ordinal term (e.g., “first,” “second,” “third,” “Nth,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

Further the terms “comprise,” “comprises,” and “comprising” may be used interchangeably with “include,” “includes,” or “including.” Additionally, the term “wherein” may be used interchangeably with “where.” As used herein, “exemplary” may indicate an example, an implementation, and/or an aspect, and should not be construed as limiting or as indicating a preference or a preferred implementation.

In the present disclosure, terms may be used to describe how one or more operations are performed, such terms include “determining,” “obtaining,” “calculating,” “estimating,” “shifting,” “adjusting,” etc. Such terms are not to be construed as limiting and other techniques may be utilized to perform similar operations. Additionally, as referred to herein, “generating,” “obtaining,” “calculating,” “estimating,” “using,” “selecting,” “accessing,” and “determining” may be used interchangeably. For example, “generating,” “obtaining,” “calculating,” “estimating,” or “determining” a parameter (or a signal) may refer to actively generating, estimating, calculating, or determining the parameter (or the signal) or may refer to using, selecting, or accessing the parameter (or signal) that is already generated, such as by another component or device.

As used herein, “coupled” may include “communicatively coupled,” “electrically coupled,” or “physically coupled,” and may also (or alternatively) include any combinations thereof. Two devices (or components) may be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled may be included in the same device or in different devices and may be connected via electronics, one or more connectors, or inductive coupling, as illustrative, non-limiting examples. In some implementations, two devices (or components) that are communicatively coupled, such as in electrical communication, may send and receive electrical signals (digital signals or analog signals) directly or indirectly, such as via one or more wires, buses, networks, etc. As used herein, “directly coupled” may include two devices that are coupled (e.g., communicatively coupled, electrically coupled, or physically coupled) without intervening components.

As used herein, the term “machine learning” should be understood to have any of its usual and customary meanings within the fields of computers science and data science, such meanings including, for example, processes or techniques by which one or more computers can learn to perform some operation or function without being explicitly programmed to do so. As a typical example, machine learning can be used to enable one or more computers to analyze data to identify patterns in data and generate a result based on the analysis. For certain types of machine learning, the results that are generated include data that indicates an underlying structure or pattern of the data itself. Such techniques, for example, include so called “clustering” techniques, which identify clusters (e.g., groupings of data elements of the data).

For certain types of machine learning, the results that are generated include a data model, which may also be referred to as a “machine-learning model”. Typically, a machine-learning model is generated using a first data set to facilitate analysis of a second data set. For example, a first portion of a large body of data may be used to generate a machine-learning model that can be used to analyze the remaining portion of the large body of data. As another example, a set of historical data can be used to generate a machine-learning model that can be used to analyze future data.

Since a machine-learning model can be used to evaluate a set of data that is distinct from the data used to generate the machine-learning model, machine-learning models can be viewed as a type of software (e.g., instructions, parameters, or both) that is automatically generated by the computer(s) during the machine learning process. As such, machine-learning models can be portable (e.g., can be generated at a first computer, and subsequently moved to a second computer for further training, for use, or both). Additionally, a machine-learning model can be used in combination with one or more other machine-learning models to perform a desired analysis. To illustrate, first data can be provided as input to a first machine-learning model to generate first model output data, which can be provided (alone, with the first data, or with other data) as input to a second machine-learning model to generate second model output data indicating a result of a desired analysis. Depending on the analysis and data involved, different combinations of machine-learning models may be used to generate such results. In some examples, multiple machine-learning models may provide model output that is input to a single machine-learning model. In some examples, a single machine-learning model provides model output to multiple machine-learning models as input.

Examples of machine-learning models include, without limitation, perceptrons, neural networks, support vector machines, regression models, decision trees, Bayesian models, Boltzmann machines, adaptive neuro-fuzzy inference systems, as well as combinations, ensembles and variants of these and other types of models. Variants of neural networks include, for example and without limitation, prototypical networks, autoencoders, transformers, self-attention networks, convolutional neural networks, deep neural networks, deep belief networks, etc. Variants of decision trees include, for example and without limitation, random forests, boosted decision trees, etc.

Since machine-learning models are generated by computer(s) based on input data, machine-learning models can be discussed in terms of at least two distinct time windows-a creation/training phase and a runtime phase. During the creation/training phase, a machine-learning model is created, trained, adapted, validated, or otherwise configured by the computer based on the input data (which in the creation/training phase, is generally referred to as “training data”). Note that the trained model corresponds to software that has been generated and/or refined during the creation/training phase to perform particular operations, such as classification, prediction, encoding, or other data analysis or data synthesis operations. During the runtime phase (or “inference” phase), the machine-learning model is used to analyze input data to generate model output. The content of the model output depends on the type of model. For example, a machine-learning model can be trained to perform classification tasks or regression tasks, as non-limiting examples. In some implementations, a machine-learning model may be continuously, periodically, or occasionally updated, in which case training time and runtime may be interleaved or one version of the machine-learning model can be used for inference while a copy is updated, after which the updated copy may be deployed for inference.

In some implementations, a previously generated model is trained (or re-trained) using a machine-learning technique. In this context, “training” refers to adapting the machine-learning model or parameters of the machine-learning model to a particular data set. Unless otherwise clear from the specific context, the term “training” as used herein includes “re-training” or refining a machine-learning model for a specific data set. For example, training may include so called “transfer learning.” As described further below, in transfer learning a base model may be trained using a generic or typical data set, and the base model may be subsequently refined (e.g., re-trained or further trained) using a more specific data set.

A data set used during training is referred to as a “training data set” or simply “training data”. The data set may be labeled or unlabeled. “Labeled data” refers to data that has been assigned a categorical label indicating a group or category with which the data is associated, and “unlabeled data” refers to data that is not labeled. Typically, “supervised machine-learning processes” use labeled data to train a machine-learning model, and “unsupervised machine-learning processes” use unlabeled data to train a machine-learning model; however, it should be understood that a label associated with data is itself merely another data element that can be used in any appropriate machine-learning process. To illustrate, many clustering operations can operate using unlabeled data; however, such a clustering operation can use labeled data by ignoring labels assigned to data or by treating the labels the same as other data elements.

Machine-learning models can be initialized from scratch (e.g., by a user, such as a data scientist) or using a guided process (e.g., using a template or previously built model). Initializing the machine-learning model includes specifying parameters and hyperparameters of the machine-learning model. “Hyperparameters” are characteristics of a machine-learning model that are not modified during training, and “parameters” of the machine-learning model are characteristics of the machine-learning model that are modified during training. The term “hyperparameters” may also be used to refer to parameters of the training process itself, such as a learning rate of the training process. In some examples, the hyperparameters of the machine-learning model are specified based on the task the machine-learning model is being created for, such as the type of data the machine-learning model is to use, the goal of the machine-learning model (e.g., classification, regression, anomaly detection), etc. The hyperparameters may also be specified based on other design goals associated with the machine-learning model, such as a memory footprint limit, where and when the machine-learning model is to be used, etc.

Model type and model architecture of a machine-learning model illustrate a distinction between model generation and model training. The model type of a machine-learning model, the model architecture of the machine-learning model, or both, can be specified by a user or can be automatically determined by a computing device. However, neither the model type nor the model architecture of a particular machine-learning model is changed during training of the particular machine-learning model. Thus, the model type and model architecture are hyperparameters of the machine-learning model and specifying the model type and model architecture is an aspect of model generation (rather than an aspect of model training). In this context, a “model type” refers to the specific type or sub-type of the machine-learning model. As noted above, examples of machine-learning model types include, without limitation, perceptrons, neural networks, support vector machines, regression models, decision trees, Bayesian models, Boltzmann machines, adaptive neuro-fuzzy inference systems, as well as combinations, ensembles and variants of these and other types of models. In this context, “model architecture” (or simply “architecture”) refers to the number and arrangement of model components, such as nodes or layers, of a machine-learning model, and which model components provide data to or receive data from other model components. As a non-limiting example, the architecture of a neural network may be specified in terms of nodes and links. To illustrate, a neural network architecture may specify the number of nodes in an input layer of the neural network, the number of hidden layers of the neural network, the number of nodes in each hidden layer, the number of nodes of an output layer, and which nodes are connected to other nodes (e.g., to provide input or receive output). As another non-limiting example, the architecture of a neural network may be specified in terms of layers. To illustrate, the neural network architecture may specify the number and arrangement of specific types of functional layers, such as long-short-term memory (LSTM) layers, fully connected (FC) layers, convolution layers, etc. While the architecture of a neural network implicitly or explicitly describes links between nodes or layers, the architecture does not specify link weights. Rather, link weights are parameters of a machine-learning model (rather than hyperparameters of the machine-learning model) and are modified during training of the machine-learning model.

Another example of training a previously generated machine-learning model is transfer learning. “Transfer learning” refers to initializing a machine-learning model for a particular data set using a machine-learning model that was trained using a different data set. For example, a “general purpose” machine-learning model can be trained to detect anomalies in vibration data associated with a variety of types of rotary equipment, and the general-purpose machine-learning model can be used as the starting point to train a machine-learning model for one or more specific types of rotary equipment, such as a first machine-learning model for generators and a second machine-learning model for pumps. As another example, a general-purpose natural-language processing model can be trained using a large selection of natural-language text in one or more target languages. In this example, the general-purpose natural-language processing model can be used as a starting point to train one or more models for specific natural-language processing tasks, such as translation between two languages, question answering, or classifying the subject matter of documents. As another example, a plurality of virtual sensors may be developed for a monitored system based on historical sensor data from a particular set of sensors. In this example, a first sensor of the particular set of sensors fails and is replaced by a substitute sensor, and rather than generating new historical sensor data with a set of sensors that includes the substitute sensor, the virtual sensors developed based on the particular set of sensors are used with input based on sensor data from the substitute sensor in place of input from the first sensor. As another example, a general-purpose image processing model can be trained using a large selection of waveform return data. In this example, the general-purpose image processing model can be used as a starting point to train one or more models for a specific observed area (e.g., a specific geographic region). In some situations, some or all of the data used to train a general-purpose machine-learning model can include simulated data (e.g., simulated waveform returns), and some or all of the training data used during transfer learning to refine the general-purpose machine-learning model can include real-world data (e.g., waveform returns gathered during real-world sampling events). Often, transfer learning can converge to a useful machine-learning model more quickly than building and training the machine-learning model from scratch. In general, a machine-learning model can be configured to perform some task or set of tasks, where “configuring” a machine-learning model in this context includes determining or setting an architecture of the machine-learning model, determining or setting hyperparameters of the machine-learning model, and training (optionally including retraining) the machine-learning model, and possibly other operations, to enable the machine-learning model to perform the task(s).

Training a machine-learning model based on a training data set generally involves changing parameters of the machine-learning model with a goal of causing the output of the machine-learning model to have particular characteristics based on data input to the machine-learning model. To distinguish from model generation operations, model training may be referred to herein as optimization or optimization training. In this context, “optimization” refers to improving a metric, and does not mean finding an ideal (e.g., global maximum or global minimum) value of the metric. Examples of optimization trainers include, without limitation, backpropagation trainers, derivative free optimizers (DFOs), and extreme learning machines (ELMs). As one example of training a machine-learning model, during supervised training of a neural network, an input data sample is associated with a label. When the input data sample is provided to the machine-learning model, the machine-learning model generates output data, which is compared to the label associated with the input data sample to generate an error value. Parameters of the machine-learning model are modified in an attempt to reduce (e.g., optimize) the error value.

As another example, to use supervised training to train a machine-learning model to perform a classification task, each data element of a training data set may be labeled to indicate a category or categories to which the data element belongs. In this example, during the creation/training phase, data elements are input to the machine-learning model being trained, and the machine-learning model generates output indicating categories to which the machine-learning model assigns the data elements. The category labels associated with the data elements are compared to the categories assigned by the machine-learning model. The computer modifies the machine-learning model until the machine-learning model accurately and reliably (e.g., within some specified criteria) assigns the correct labels to the data elements. In this example, the machine-learning model can subsequently be used (in a runtime phase) to receive unknown (e.g., unlabeled) data elements, and assign labels to the unknown data elements. In an unsupervised training scenario, the labels may be omitted. During the creation/training phase, model parameters may be tuned by the training algorithm in use such that during the runtime phase, the machine-learning model is configured to determine which of multiple unlabeled “clusters” an input data sample is most likely to belong to.

As another example, to train a machine-learning model to perform a regression task, during the creation/training phase, one or more data elements of the training data are input to the machine-learning model being trained, and the machine-learning model generates output indicating a predicted value of one or more other data elements of the training data. The predicted values of the training data are compared to corresponding actual values of the training data, and the computer modifies the machine-learning model until the machine-learning model accurately and reliably (e.g., within some specified criteria) predicts values of the training data. In this example, the machine-learning model can subsequently be used (in a runtime phase) to receive data elements and predict values that have not been received. To illustrate, the machine-learning model can analyze time-series data, in which case, the machine-learning model can predict one or more future values of the time series based on one or more prior values of the time series.

In some aspects, the output of a machine-learning model can be subjected to further analysis operations to generate a desired result. To illustrate, in response to particular input data, a classification model (e.g., a machine-learning model trained to perform classification tasks) may generate output including an array of classification scores, such as one score per classification category that the machine-learning model is trained to assign. Each score is indicative of a likelihood (based on the machine-learning model's analysis) that the particular input data should be assigned to the respective category. In this illustrative example, the output of the machine-learning model may be subjected to a softmax operation to convert the output to a probability distribution indicating, for each category label, a probability that the input data should be assigned the corresponding label. In some implementations, the probability distribution may be further processed to generate a one-hot encoded array. In other examples, other operations that retain one or more category labels and a likelihood value associated with each of the one or more category labels can be used.

FIG. 1 is a diagram illustrating particular aspects of a system 100 to generate simulated sensor readings for one or more second sensors 102 of a monitored system 104 using corresponding virtual sensors 106 for the one or more second sensors 102, in accordance with some aspects of the present disclosure. In FIG. 1, the system 100 includes the monitored system 104, one or more control systems 108, and a virtual sensor generator 110.

The monitored system 104 includes sensors 112 and one or more control devices 116. The sensors 112 provide sensor data 114 to the control system(s) 108. The sensors 112 may include one type of sensor or multiple types of sensors. For example, the monitored system 104 may be a subsea well (e.g., a subsea oil well), and the sensors 112 may include well head sensors located at or near a well head of the subsea well, well bore sensors located in or near a well bore of the subsea well. The sensors 112 may include temperature sensors, pressure sensors, flow rate sensors, composition sensors, other types of sensors, or combinations thereof. The sensors 112 may include first sensors 118 that are operational to provide the sensor data 114 (e.g., voltage signals) to the control system(s) 108, and the control system(s) 108 determines input data (e.g., sensor readings) from the sensor data 114. For a particular time frame of operation of the monitored system 104, all of the sensors 112 are first sensors 118, but beginning at some particular time, one or more of the sensors 112 may become non-operational (e.g., fail to provide sensor data 114 or provide unreliable sensor data 114). The sensor(s) 102 are one or more of the sensors 112 that are non-operational sensors (e.g., failed sensors) that do not generate sensor data 114 or generate unreliable sensor data 114.

The control device(s) 116 receives control signals 120 from the control system(s) 108. The control device(s) 116 are devices that can change operating conditions of the monitored system 104 (e.g., pumps, control valves, heaters, coolers, etc.). The control signals 120 received by a control device 116 are utilized by the control device 116 to maintain or adjust operating conditions of the monitored system 104 so that sensor readings associated with particular first sensors 118, or sensor readings provided by one or more virtual sensors 106 that correspond to sensor(s) 102, are at or approach one or more setpoint values, are within one or more desired operational ranges, or both. For example, during drilling of an oil well, a first plurality of the sensors 112 are pressure sensors that measure downhole pressure in an annular region between a drill casing and a drill string. During drilling, the control system 108 provides control signals 120 to one or more particular control devices 116 (e.g., drilling mud pumps) to control the amount of drilling mud pumped into the oil well to maintain the pressure in the annular region within a particular pressure range and to bring the pressure in the annular region to, or close to, a particular setpoint pressure.

The control system(s) 108 includes one or more interfaces 122, one or more memory devices 124, one or more processors 126, other components, or combinations thereof. The interface(s) 122 receives sensor data 114 from the sensors 112 of the monitored system 104, sends control signals 120 to the control device(s) 116, and facilitates communication with the virtual sensor generator 110.

The memory device(s) 124 store information. The information includes data 128 and instructions 130. The data 128 includes information used by and generated by the processor(s) 126.

The processor(s) 126 is configured to execute instructions 130 stored in the memory device(s) 124 to perform operations. The processor(s) 126 can be implemented as a single processor or as multiple processors, such as in a multi-core configuration, a multi-processor configuration, a distributed computing configuration, a cloud computing configuration, or any combination thereof.

The processor(s) 126 includes a preprocessor 132, a controller 134, and virtual sensors 106. In some implementations, one or more portions of the preprocessor 132, the controller 134, the virtual sensors 106, or a combination thereof, are implemented by the processor(s) 126 using dedicated hardware, firmware, or a combination thereof. In some implementations, one or more portions of the preprocessor 132, the controller 134, the virtual sensors 106, or a combination thereof, can be implemented at least in part by the processor(s) 126 executing the instructions 130 stored in the memory device(s) 124.

The preprocessor 132 is configured to process sensor data 114 received from the first sensors 118 of the monitored system 104 to input data (e.g., sensor readings (e.g., temperature, pressure, flow rate, etc.)) associated with corresponding types of first sensors 118. For each first sensor 118, the preprocessor 132 determines whether sensor data 114 from the first sensor 118 is reliable based on one or more rules, and if the sensor data 114 from the first sensor 118 is not reliable, the first sensor 118 is identified as a second sensor 102. The rules identify characteristics associated with unreliable sensors, such as no received sensor data 114 for a first threshold time period, a particular number of sensor readings determined from the sensor data 114 that corresponding to sensor readings outside of acceptable ranges for the type of first sensor 118 within a second threshold time period, a constant value for the sensor data for a third threshold time period when one or more similar first sensors 118 or one or more other types of first sensors 118 indicate that the sensor data should be varying, etc. When the preprocessor 132 identifies a second sensor 102, an identifier of the second sensor 102 is stored in a second sensor list 136 in the data 128.

The preprocessor 132 causes sensor readings corresponding to reliable sensor data 114 to be saved as historical sensor data 138. The controller 134, the virtual sensors 106, or both, also receive the sensor readings corresponding to reliable sensor data 114 or access these sensor readings from the historical sensor data 138.

When the preprocessor 132 identifies a particular second sensor 102, the control system 108 may also provide output (e.g., visual output to one or more display devices, audio output, haptic output, or combinations thereof) that indicates an issue with the second sensor 102 to operator(s) associated with the monitored system 104. In some implementations, the output may include an error metric. The processor(s) may generate the error metric by accessing the historical sensor data 138, determining a statistically significant filtered set of recent sensor data, generating simulated sensor readings for the virtual sensor(s) 106 corresponding to the particular second sensor 102 for the filtered set of recent data, and generating the error metric (e.g., mean absolute percentage error, mean absolute error, root mean square error, or some other error metric for the set) based on the simulated sensor readings and the corresponding actual sensor readings. If the error metric does not satisfy a threshold for the error metric, the processor(s) 126 may send a request to the virtual sensor generator 110 to update the virtual sensor(s) 106 corresponding to the second sensor 102, and the output may indicate to the operator(s) of the monitored system 104 that the monitored system 104 should be operated in a conservative manner, or be shut down, until second sensors 102 identified in the second sensor list 136 can be replaced or an updated virtual sensor 106 corresponding to the second sensor 102 is provided by the virtual sensor generator 110.

In addition to generating the error metric in response to identification of a second sensor 102, the processor(s) 126 may periodically, or in response to user input, generate error metrics for particular ones of the virtual sensors 106 based on filtered sets of recent historical sensor data 138 (e.g., historic sensor data 138 within a month, a week, a day, or some other time period of a present time). For each error metric that does not satisfy the threshold for the error metric, the processor(s) 126 may send a request to the virtual sensor generator 110 to update the virtual sensor 106 corresponding to the error metric, provide output to the operator(s) indicating an issue with the virtual sensor 106 for the second sensor 102 based on the error metric, or both.

In some implementations, the virtual sensors 106 are periodically scheduled to be updated because accuracy of the virtual sensors 106 may decline with the passage of time. Requests to update virtual sensors 106 corresponding to first sensors 118 may be automatically sent by the processor(s) 126 to the virtual sensor generator 110 at scheduled times. Request to update virtual sensors 106 corresponding to second sensors are not sent by the processor(s) 126 since the second sensors are not providing reliable sensor data. At the scheduled time for a particular second sensor 102, the processor(s) 126 may send output (e.g., to a display device) to inform the operator(s) of possible degradation of accuracy of the simulated sensor readings for the particular second sensor 102, which may be a basis for the operator(s) to change operation characteristics of the monitored system 104 (e.g., conservatively operate the monitored system).

In some implementations, the preprocessor 132 determines a regime associated with operation of the monitored system 104 based on the sensor data 114, historical sensor data 138, or both. When the second sensor list 136 includes identifiers of one or more second sensors 102, a determination of a particular virtual sensor 106 to use to generate a sensor reading for a particular second sensor 102 identified in the second sensor list 136 is made based on the regime. For example, when the preprocessor 132 identifies the regime as a startup regime based on the sensor data 114 and the historical sensor data 138, the control system 108 uses a first particular virtual sensor 106 associated with the startup regime to generate a simulated sensor reading corresponding to a first particular second sensor 102 identified in the second sensor list 136; and, when the preprocessor 132 identifies the regime as a steady operation regime based on the sensor data 114 and the historical sensor data 138, the control system 108 uses a second particular virtual sensor 106 associated with the steady operation regime to generate the simulated sensor reading corresponding to the first particular second sensor 102.

The controller 134 determines control signals 120 to send to the control devices 116 to control operation of the monitored system 104 and the processor(s) 126 send the control signals to the control devices 116. The control signals 120 may be based on sensor readings for the first sensors 118 determined by the preprocessor 132; based on simulated sensor readings associated with the one or more second sensors 102 when one or more second sensors 102 are identified in the second sensor list 136; based on operational ranges for sensor readings, based on one or more user input setpoints; based on one or more calculated setpoints; based on other information, or combinations thereof. The controller 134 receives the sensor readings for the first sensors 118 from the preprocessor 132, retrieves recently saved sensor readings for the first sensors 118 from the historical sensor data 138, or both. When the second sensor list 136 includes identifiers of one or more second sensors 102, the controller 134 receives simulated sensor readings for the one or more second sensors 102 from the virtual sensors 106.

The virtual sensors 106 may include a virtual sensor 106 for each of the sensors 112 or for a subset of the sensors 112. The virtual sensors 106 may include multiple virtual sensors corresponding to a particular sensor 112 when the monitored system 104 is associated with two or more regimes. The virtual sensor generator 110 provides the virtual sensors 106 to the control system(s) 108 and the virtual sensor generator 110 may update the virtual sensors 106 periodically or based on requests received from one of the control system(s) 108.

Each virtual sensor 106 includes a plurality of regression models 140 and a confidence estimate generator 142. The regression models 140 are trained by the virtual sensor generator 110 using the historical sensor data 138. At least two of the regression models are trained using different sets of the training data formed from the historical sensor data. The plurality of regression models 140 for a particular virtual sensor 106 receive sensor readings corresponding to all or a subset of the first sensors 118 as input data. The input data excludes data for a particular sensor 112 corresponding to the particular virtual sensor 106. The particular virtual sensor 106 generates a simulated sensor reading for the particular sensor 112 as output. In some implementations when the second sensor list 136 includes identifiers of more than one second sensor 102, a simulated sensor reading produced by a first virtual sensor 106 for a first particular second sensor 102 identified in the second sensor list 136 is provided as part of the input data for a second virtual sensor for a second particular second sensor 102 identified in the second sensor list 136. The confidence estimate generator 142 generates a confidence estimate associated with a sensor reading for a virtual sensor 106 generated using corresponding regression models 140.

When a particular virtual sensor 106 is used to generate a simulated sensor reading for a second sensor 102, the simulated sensor reading generated using the plurality of regression models 140 is provided to the controller 134. The controller 134 may use the simulated sensor reading in determining one or more control signals 120 to be sent by the control system(s) to the control device(s) 116. When the second sensor list 136 includes one or more second sensors 102, the confidence estimates produced by the confidence estimate generator 142, the simulated sensor readings, actual sensor readings from first sensors 118 that are of the same type as the second sensor 102 and near to the second sensor 102, or combinations thereof, may be provided as output (e.g., tabular data, one or more graph representations, or both, to a display device) for each second sensor 102 to enable the operator(s) of the monitored system 104 to determine whether to continue operation of the monitored system 104 in an unchanged manner, to conservatively operate the monitored system 104, or to halt operation of the monitored system 104. In response to a mean of a plurality of confidence estimates being less than a confidence estimate threshold, the control system(s) 108 may generate an alert (e.g., an audio alert and text explaining the alert, emphasized indicia in the output, or combinations thereof). The alert may indicate that the monitored system 104 should be operated more conservatively or be shut down.

Each regression model 140 for a particular virtual sensor 106 corresponding to a second sensor 102 generates an individual estimate of the sensor reading of the second sensor 102 using sensor readings determined from sensor data 114 of at least a portion of the first sensors 118 as input data, wherein the input data excludes data for the sensor 112 corresponding to the particular virtual sensor 106. The simulated sensor reading provided to the controller 134 for the second sensor 102 is determined based on the individual estimates generated using the regression models 140. For example, the simulated sensor reading may be determined as a mean of the individual estimates of the sensor readings.

The confidence estimate produced by the confidence estimate generator 142 for a particular virtual sensor 106 corresponding to a second sensor 102 may indicate whether individual estimates of the sensor reading generated by the plurality of regression models 140 are producing values that are reasonable relative to each other. In some implementations, the confidence estimate may be expressed as a percentage. A high percentage may indicate a narrow range between a largest individual sensor reading generated by the regression models 140 for the particular virtual sensor 106 and a smallest individual sensor reading generated by the regression models 140 for the particular virtual sensor 106, which may indicate a high confidence that the simulated sensor reading corresponds to actual conditions associated with the second sensor 102 corresponding to the particular virtual sensor 106. A larger range between the largest individual sensor reading generated by the regression models 140 for the particular virtual sensor 106 and the smallest individual sensor reading generated by the regression models 140 for the particular virtual sensor may indicate a low confidence that the simulated sensor reading corresponds to actual conditions associated with the second sensor 102.

The confidence estimate associated with a simulated sensor reading for a particular virtual sensor 106 may be based on a range of estimated sensor readings output by the regression models 140 and historical sensor data 138 associated with the second sensor 102 corresponding to the particular virtual sensor 106. In an implementation, the confidence estimate is calculated as the difference of a noise-filtered mean of training target data for the second sensor 102 and a portion of the range (e.g., the portion of the range corresponding to quantile (0.68)-quantile (0.32)) divided by the noise-filtered mean and multiplied by 100. In other implementations, a confidence estimate may be calculated in a different manner. The noise-filtered mean of the training data for the second sensor 102 is determined by the virtual sensor generator 110 based on the historical sensor data 138 when the particular virtual sensor 106 is generated by generating noise-filtered historical data by filtering out sensor readings of the training data for the second sensor 102 that are determined to be noise and determining a mean of the remaining sensor readings of the training data for the second sensor 102. The noise-filtered mean is included in the confidence estimate generator 142 of the virtual sensor 106 associated with the second sensor 102 provided by the virtual sensor generator 110 to the control system(s) 108.

The virtual sensor generator 110 generates virtual sensors 106 corresponding to particular sensors 112 of the monitored system 104. The particular sensors 112 may correspond to all sensors 112 of the monitored system 104 or a subset of sensors 112. The subset of sensors 112 may correspond to sensors 112 of the monitored system 104 that are difficult to replace due to physical factors, due to economic factors, due to other factors, or combinations thereof, may correspond to sensors that provide information used to control the monitored system 104, other selected sensors 112, or combinations thereof.

Each virtual sensor 106 generated by the virtual sensor generator 110 includes an ensemble of a particular number of regression models 140 (e.g., 30 regression models 140, 25 regression models 140, 20 regression models 140, or some other number of regression models 140) and a confidence estimate generator 142. In some implementations, the regression models 140 are all the same type of regression model 140 (e.g., extreme gradient boosting (XGB) regression models) with different hyperparameters. In other implementations, the regression models 140 may include one or more different types of regression models 140 (e.g., one or more XGB regresssors, one or more linear regressors, one or more ridge regressors, one or more neural network regressors, one or more lasso regressors, one or more decision tree regressors, one or more random forest regressors, one or more other types of regression models 140, or combinations thereof). The regression models 140 may be trained using subsets of the historical sensor data 138.

The virtual sensor generator 110 may include one or more interfaces 144, one or more processors 146, other components, or combinations thereof. The interface(s) 144 enables the virtual sensor generator 110 to communicate with other devices. The interface(s) 144 enable the virtual sensor generator 110 to receive requests to generate virtual sensors 106 for one or more monitored systems 104, enable the virtual sensor generator 110 to retrieve historical sensor data 138 for the one or more monitored systems, and enable the virtual sensor generator 110 to send virtual sensors 106 to control system(s) 108 associated with the one or more monitored systems 104. The virtual sensors 106 may be sent via one or more networks or may be transferred using one or more portable storage devices. A request to generate virtual sensors 106 may also be received by the virtual sensor generator 110 via an input device of the virtual sensor generator 110. A request to generate one or more virtual sensors 106 may identify a location of historical sensor data 138 for the monitored system 104, identifiers of the particular sensors 112 of the monitored system 104 for which virtual sensors 106 are to be generated, identification of sensor readings to be used as input data for particular virtual sensors 106, control system(s) 108 to receive the virtual sensors 106, other information, or combinations thereof. The historical sensor data 138 may be retrieved from the control system(s) 108 or from one or more data repositories external to the control system(s) 108 that receive the historical sensor data 138 from the control system(s) 108.

The processor(s) 146 enables the virtual sensor generator 110 to generate virtual sensors 106. In the example illustrated in FIG. 1, the processor(s) 146 includes a preprocessor 148, a trained regression model generator 150, and a postprocessor 152. The preprocessor 148 is configured to perform preprocessing operations to prepare the historical sensor data 138 for input to the trained regression model generator 150. For example, the preprocessor 148 may filter the historical sensor data 138 to produce filtered data, identify regimes associated with the filtered data based on one or more regime rules, separate the filtered data into training data and validation data, subdivide the training data into subsets, determine a mean of the filtered data used to train a virtual sensor 106, perform other tasks, or combinations thereof. The subsets may be formed to correspond to particular regimes associated with the monitored system 104, to reduce resources used to train regression models, to promote diversity in sensor reading estimates generated by the regression models 140, or combinations thereof. The preprocessor 148 provides the training data to the trained regression model generator 150 and the validation data to the postprocessor 152.

The trained regression model generator 150 receives an identifier of a particular sensor 112 for which a virtual sensor 106 is to be created and training data for the virtual sensor 106 from the preprocessor 148. The training data includes actual sensor readings for the particular sensor 112 and sensor readings for other sensors 112 for a period of time. The trained regression model generator 150 generates regression models 154 that output an estimated sensor reading for the particular sensor 112 based on input data of sensor readings of other sensors 112. The regression models 154 include hyperparameters 156 and parameters 158. The regression models 154 generated by the trained regression model generator 150 may all be one type of regression model 154 (e.g., XGB regression models), or may include regression models 154 of various types (e.g., XGB regression model(s), linear regression model(s), ridge regression model(s), neural network regression model(s), lasso regression model(s), decision tree regression model(s), random forest regression model(s), etc.).

When the regression models 154 include multiple regression models 154 of the same type (e.g., multiple XGB regression models), hyperparameters 156 for the multiple regression models 154 are different. For example, the hyperparameters 156 for an XGB regression model may include categories of hyperparameters 156, including tree creation hyperparameters (e.g., max_depth, min_child_weight, and max_leaves, which relate to maximum depth of a tree to control a depth of individual decision trees, minimum sum of instance weight needed in a child to prevent overly specific trees by setting, and number of leaves in a tree, respectively), categorical data hyperparameters (e.g., enable-categorical, max_cat_to_onchot, and max_cat_threshold, which relate to a flag to enable handling of categorical features, a threshold for deciding whether XGBoost should use one-hot encoding based split for categorical data, and maximum number of categories considered for each split, respectively), and other categories. Regression models 154 of the same type include different hyperparameters 156 so that resulting trained regression models, even when trained with the same training data set, have different parameters 158 and are capable of generating different output for the same input.

The trained regression model generator 150 determines the parameters 158 of each regression model 154 using the hyperparameters 156 and a particular set of training data to generate a trained regression model. For input data of sensor readings for sensors 112 other than the particular sensor 112, each trained regression model outputs an estimated sensor reading for the particular sensor 112 that is, or is close to, the actual sensor reading associated with the input data.

The trained regression model generator 150 provides each trained regression model to the postprocessor 152. The trained regression model generator 150 continues to generate trained regression models until the trained regression model generator 150 receives a notification from the postprocessor 152 that indicates that the virtual sensor 106 can be generated, or a threshold number of attempts to form trained models from regression models 154 and trained models is exceeded. If the threshold number is exceeded, a warning may be generated and presented to personnel associated with the virtual sensor generator 110 to indicate that the virtual sensor 106 for the particular sensor 112 could not be generated. In response, the personnel may analyze the training data and define one or more regimes or implement other solutions to allow one or more virtual sensors 106 corresponding to the particular sensor 112 to be developed.

The postprocessor 152 receives trained regression models from the trained regression model generator 150 for the particular sensor 112. The postprocessor 152 determines an error metric for each trained regression model based on the validation data received from the preprocessor 148. When the error metric for a particular trained model fails to satisfy a threshold value (e.g., the error metric is greater than 5%, 10%, or some other value when the error metric is a mean absolute percentage error), the particular trained model is discarded, and the postprocessor 152 provides data identifying the particular trained model to the trained regression model generator 150 to enable the trained regression model generator 150 to reuse the training data used to train the particular trained model. When the particular trained model satisfies the threshold value (e.g., the error metric is less than or equal to the threshold value), the trained model is saved.

When the number of saved trained modes for the particular sensor 112 is equal to the particular number of regression models 140, the postprocessor 152 provides notification to the trained regression model generator 150 that causes the trained regression model generator 150 to stop providing trained models for the particular sensor 112 to the postprocessor 152. If the number of saved trained models is greater than the particular number, trained sensor models with highest error metrics are discarded until the number of saved trained models equals the particular number.

The postprocessor 152 generates instructions (e.g., software) that correspond to the virtual sensor 106 for the particular sensor 112. The virtual sensor 106 includes the saved trained regression models as the regression models 140, instructions to generate individual sensor readings from input data for each of the regression models 140, and instructions to generate a simulated sensor reading from the individual sensor readings. The virtual sensor 106 also includes the confidence estimate generator 142, which includes instructions to determine a confidence estimate for the simulated sensor reading based on a range of the individual sensor readings and based on a mean of the filtered sensor readings used to train the regression models 140.

The virtual sensor generator 110 generates a virtual sensor 106 for each sensor 112 identified as needing a virtual sensor 106 in the request. The generated virtual sensors 106 are provided by the virtual sensor generator 110 to appropriate control system(s) 108 identified in the request.

The virtual sensor generator 110 is able to generate virtual sensors 106 for a monitored system 104 and utilize the virtual sensors 106 to generate simulated sensor readings for one or more second sensors 102 that have failed, or for one or more operational sensors 118 in order to check accuracy of the simulated sensor readings generated by the corresponding virtual sensor(s) as compared to actual sensor readings determined from sensor data 114 for the one or more operational sensors 118. Output of the virtual sensors may include a confidence estimate, which can allow operator(s) of the virtual sensor to determine how to adjust to the failure of the one or more second sensors 102. The virtual sensors are generated by the virtual sensor generator 110 based on historical sensor data 138 for the monitored system. The virtual sensor 106 for a particular second sensor 102 receives input of sensor readings of other sensors 112 of the monitored system 104 and generates a simulated sensor reading for the particular second sensor 102. The simulated sensor reading may be used by the control system(s) to generate control signals for the monitored system. The virtual sensors 106 enable continued operation of the monitored system 104 until second sensors 102 that have failed can be replaced, or enables extended operation of the monitored system when the second sensors cannot be replaced.

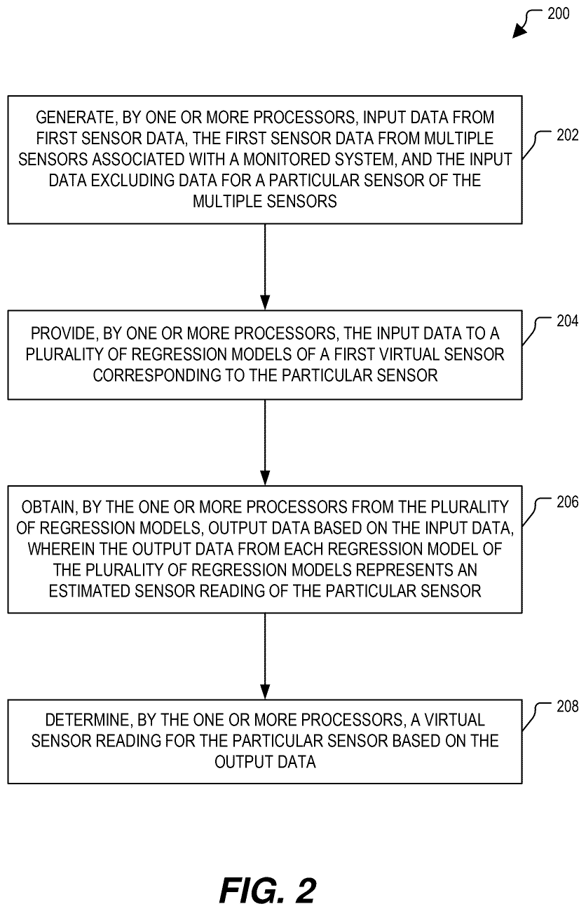

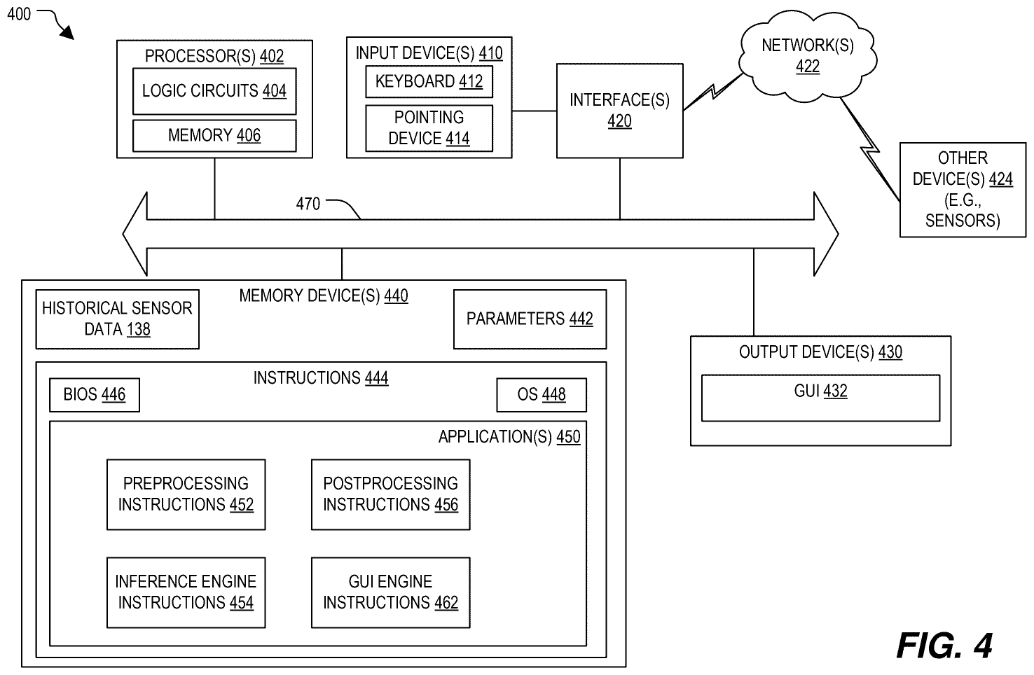

FIG. 2 illustrates a flow chart of an example of a method of generating a simulated sensor reading for a particular sensor of a monitored system based on sensor readings of other sensors of the monitored system. One or more operations described with reference to FIG. 2 may be performed by the system 100 of FIG. 1, such as by one or more computing devices that include the processor(s) 126. Also, one or more of the operations described with reference to FIG. 2 may be performed by the computer system 400 of FIG. 4, such as by processor(s) 402 executing instructions 444, which corresponds to the processor(s) 126 of FIG. 1.

The method 200 includes, at block 202, generating, by one or more processors, input data from first sensor data. The first sensor data is from multiple sensors associated with a monitored system. Also, the input data excludes data for a particular sensor of the multiple sensors. For example, the processor(s) 126 (or a component thereof, such as the preprocessor 132) can receive sensor data 114 from the first sensors 118 of the monitored system 104 and convert the sensor data 114 to input data including sensor readings. The input data excludes data for a particular sensor of the multiple sensors 112. The particular sensor corresponds to a second sensor 102 that has failed or is unreliable, or to an operational sensor. The operational sensor may be identified by user input or by the one or more processor(s) 126 in order to determine accuracy of simulated sensor readings from a corresponding virtual sensor as compared to actual sensor readings determined from sensor data 114 for the operational sensor. In some implementations, the processor(s) 126 can also, based on the first sensor data, determine a regime of the monitored system 104, determine whether one or more sensors 112 of the monitored system 104 are reliable or unreliable, store sensor readings from sensors 112 that are reliable as historical sensor data 138, identify an unreliable sensor as a second sensor 102, remove an identifier of a reliable sensor from a second sensor list, add an identifier of an unreliable sensor to the second sensor list 136, or combinations thereof.

The method 200 includes, at block 204, providing, by the one or more processors, the input data to a plurality of regression models of a first virtual sensor corresponding to the particular sensor. For example, the processor(s) 126 (or a component thereof, such as the preprocessor 132) can provide the input data as input to a first virtual sensor 106. The first virtual sensor 106 corresponds to the particular sensor.

The method 200, at block 206, includes obtaining, by the one or more processors from the plurality of regression models, output data based on the input data. The output data from each regression model of the plurality of regression models represents an estimated sensor reading of the particular sensor. For example, the processor(s) 126 (or a component thereof, such as the first virtual sensors 106) processes the input data with each regression model of the first virtual sensor 106 to generate output of an estimated sensor reading of the particular sensor.

The method 200, at block 208, also includes determining, by the one or more processors, a simulated sensor reading for the particular sensor based on the output data. For example, the processor(s) 126 (or a component thereof, such as the first virtual sensor 106) determines the simulated sensor reading as a mean of the estimated sensor readings output by the regression models 140 of the first virtual sensor 106.

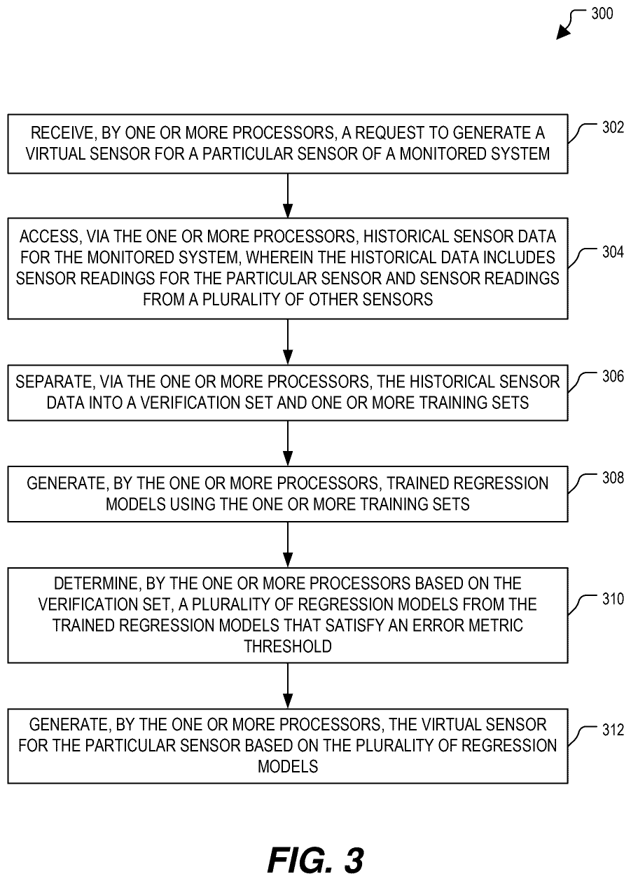

FIG. 3 illustrates a flow chart of an example of a method of generating a virtual sensor for a particular sensor of a monitored system. One or more operations described with reference to FIG. 3 may be performed by the system 100 of FIG. 1, such as by one or more computing devices that include the processor(s) 146. Also, one or more of the operations described with reference to FIG. 3 may be performed by the computer system 400 of FIG. 4, such as by processor(s) 402 executing instructions 444, which corresponds to the processor(s) 146 of FIG. 1.

The method 300, at block 302, includes receiving, by one or more processors, a request to generate a virtual sensor for a particular sensor of a monitored system. For example, the processor(s) 146 may receive a request to generate the virtual sensor 106 for a particular sensor 112 of the monitored system 104 from a control system 108 or via user input from an input device coupled to the processor(s) 146.

The method 300, at block 304, includes accessing, via the one or more processors, historical sensor data for the monitored system, wherein the historical data includes sensor readings for the particular sensor and sensor readings from a plurality of other sensors. For example, the processor(s) 146 may access historical sensor data 138 for the monitored system 104 from the control system(s) 108 or from a data repository.

The method 300, at block 306, includes separating, via the one or more processors, the historical sensor data into a verification set and one or more training sets. For example, the processor(s) 146 (or a component thereof, such as the preprocessor 148) separates the historical sensor data 138 into a verification set that is provided to the postprocessor 152 and one or more training sets that is provided to the trained regression model generator 150.

The method 300, at block 308, includes generating, by the one or more processors, trained regression models using the one or more training sets. For example, the processor(s) 146 (or a component thereof, such as the trained regression model generator 150) generates trained regression models by adjusting parameters of each regression model based on hyperparameters of the regression model and a training set of the one or more training sets. The trained regression models are provided to the postprocessor 152.

The method 300, at block 310, includes determining, by the one or more processors based on the verification set, a plurality of regression models from the trained regression models that satisfy an error metric threshold. For example, the processor(s) 146 (or a component thereof, such as the postprocessor 152) determines an error metric for each trained regression model using the verification data. In some implementations, the error metric is a mean absolute percentage error calculated using the equation:

$$mean absolute \% error = \frac{1}{n} {\sum }_{i = 0}^{n} \vert \frac{{y}_{i , p r e d} - {y}_{i , actual}}{{y}_{i , actual}} \vert \times 100$$

where n is a number of samples, i is a counter, y_{i,pred} is a simulated sensor reading generated by the virtual sensor 106, and y_{i,actual} is an actual sensor reading determined from sensor data. Each error metric is compared to an error metric threshold. If the error metric threshold is less than or equal to the error metric threshold for a trained regression model, the trained regression model is discarded. If the error metric threshold is greater than the error metric threshold for the trained regression model, the regression model is saved as one of a plurality of regression models. In other implementations, a different error metric can be used instead of the mean absolute percentage error.

The method 300, at block 312, also includes generating, by the one or more processors, the virtual sensor for the particular sensor based on the plurality of regression models. For example, the processor(s) 146 (or a component thereof, such as the postprocessor 152) generates the virtual sensor 106 for the particular sensor 112 when the number of regression models of the plurality of regression models equals a number of regression models used to generate a virtual sensor. The virtual sensor 106 for the particular sensor 112 is configured to determine a simulated sensor reading for the particular sensor 112 based on input data of sensor readings from other sensors 112 of the monitored system 104. The virtual sensor 106 for the particular sensor 112 may be provided to one or more devices specified in the request.

FIG. 4 illustrates an example of a computer system 400 configured to generate and use virtual sensors. For example, the computer system 400 is configured to initiate, perform, or control one or more of the operations described with reference to FIGS. 1-3. The computer system 400 can be implemented as or incorporated into one or more of various other devices, such as the control system(s) 108, the virtual sensor generator 110, the sensors 112, a personal computer (PC), a tablet PC, a server computer, a personal digital assistant (PDA), a laptop computer, a desktop computer, a communications device, a wireless telephone, or any other machine capable of executing a set of instructions (sequential or otherwise) that specify actions to be taken by that machine. Further, while a single computer system 400 is illustrated, the term “system” includes any collection of systems or sub-systems that individually or jointly execute a set, or multiple sets, of instructions to perform one or more computer functions. While FIG. 4 illustrates one example of the computer system 400, other computer systems or computing architectures and configurations may be used for carrying out the operations disclosed herein.

The computer system 400 includes one or more processors 402. In this context, the term “processor” refers to an integrated circuit consisting of logic circuits 404, interconnects, input/output blocks, clock management components, memory 406, and optionally other special purpose hardware components, designed to execute instructions and perform various computational tasks. Examples of processors include, without limitation, central processing units (CPUs), digital signal processors (DSPs), neural processing units (NPUs), graphics processing units (GPUs), field programmable gate arrays (FPGAs), microcontrollers, quantum processors, coprocessors, vector processors, other similar circuits, and variants and combinations thereof.

Taking CPUs as a starting point, a CPU typically includes one or more processor cores, each of which includes a complex, interconnected network of transistors and other circuit components defining logic gates (e.g., the logic circuits 404), memory elements, etc. A core is responsible for executing instructions to, for example, perform arithmetic and logic operations. Typically, a CPU includes an Arithmetic Logic Unit (ALU) that handles mathematical operations and a Control Unit that generates signals to coordinate the operation of other CPU components, such as to manage operations of a fetch-decode-execute cycle.

CPUs and/or individual processor cores generally include local memory circuits (e.g., the memory 406), such as registers and cache to temporarily store data during operations. Registers include high-speed, small-sized memory units intimately connected to the logic cells of a CPU. Often registers include transistors arranged as groups of flip-flops, which are configured to store binary data. Caches include fast, on-chip memory circuits used to store frequently accessed data. Caches can be implemented, for example, using Static Random-Access Memory (SRAM) circuits.

Operations of a CPU (e.g., arithmetic operations, logic operations, and flow control operations) are directed by software and firmware. At the lowest level, the CPU includes an instruction set architecture (ISA) that specifies how individual operations are performed using hardware resources (e.g., registers, arithmetic units, etc.). Higher level software and firmware is translated into various combinations of ISA operations to cause the CPU to perform specific higher-level operations. For example, an ISA typically specifies how the hardware components of the CPU move and modify data to perform operations such as addition, multiplication, and subtraction, and high-level software is translated into sets of such operations to accomplish larger tasks, such as adding two columns in a spreadsheet. Generally, a CPU operates on various levels of software, including a kernel, an operating system, applications, and so forth, with each higher level of software generally being more abstracted from the ISA and usually more readily understandable by human users.

GPUs, NPUs, DSPs, microcontrollers, coprocessors, FPGAs, ASICS, and vector processors include components similar to those described above for CPUs. The differences among these various types of processors are generally related to the use of specialized interconnection schemes and ISAs to improve a processor's ability to perform particular types of operations. For example, the logic gates, local memory circuits, and the interconnects therebetween of a GPU are specifically designed to improve parallel processing, sharing of data between processor cores, and vector operations, and the ISA of the GPU may define operations that take advantage of these structures. As another example, ASICs are highly specialized processors that include similar circuitry arranged and interconnected for a particular task, such as encryption or signal processing. As yet another example, FPGAs are programmable devices that include an array of configurable logic blocks (e.g., interconnected sets of transistors and memory elements) that can be configured (often on the fly) to perform customizable logic functions.

A processor can be configured to perform a specific task by including, within the processor, specialized hardware to perform the task. Additionally, or alternatively, the processor can be configured to perform a specific task by loading and/or executing instructions (e.g., computer code) that, when executed, cause the processor to perform the specific task. Loading executable instructions to perform the task causes an internal configuration change in the processor that transforms what may otherwise be a general-purpose processor into a special purpose processor for performing the task.

The processor(s) 402 is configured to interact with other components or subsystems of the computer system 400 via a bus 470. The bus 470 is illustrative of any interconnection scheme serving to link the subsystems of the computer system 400, external subsystems or devices, or any combination thereof. The bus 470 includes a plurality of conductors to facilitate communication of electrical and/or electromagnetic signals between the components or subsystems of the computer system 400. Additionally, the bus 470 includes one or more bus controllers or other circuits (e.g., transmitters and receivers) that manage signaling via the plurality of conductors and that cause signals sent via the plurality of conductors to conform to particular communication protocols.

In FIG. 4, the computer system 400 includes one or more output devices 430, one or more input devices 410, and one or more interface devices 420. Each of the output device(s) 430, the input device(s) 410, and the interface device(s) 420 can be coupled to the bus 470 via a port or connector, such as a Universal Serial Bus port, a digital visual interface (DVI) port, a serial ATA (SATA) port, a small computer system interface (SCSI) port, a high-definition media interface (HDMI) port, or another serial or parallel port. In some implementations, one or more of the output device(s) 430, the input device(s) 410, and/or the interface device(s) 420 is coupled to or integrated within a housing with the processor(s) 402 and the memory device(s) 440, in which case the connections to the bus 470 can be internal, such as via an expansion slot or other card-to-card connector. In other implementations, the processor(s) 402 and the memory device(s) 440 are integrated within a housing that includes one or more external ports, and one or more of the output device(s) 430, the input device(s) 410, and/or the interface device(s) 420 is coupled to the bus 470 via the external port(s).

Examples of the output device(s) 430 include display devices, speakers, printers, televisions, projectors, or other devices to provide output of data in a manner that is perceptible by a user. Examples of the input device(s) 410 include buttons, switches, knobs, a keyboard 412, a pointing device 414, a biometric device, a microphone, a motion sensor, or another device to detect user input actions. The pointing device 414 includes, for example, one or more of a mouse, a stylus, a track ball, a pen, a touch pad, a touch screen, a tablet, another device that is useful for interacting with a graphical user interface, or any combination thereof. A particular device may be an input device 410 and an output device 430. For example, the particular device may be a touch screen.

The interface device(s) 420 are configured to enable the computer system 400 to communicate with one or more other devices 424 directly or via one or more networks 422. For example, the interface device(s) 420 may encode data in electrical and/or electromagnetic signals that are transmitted to the other device(s) 424 as control signals or packet-based communication using pre-defined communication protocols. As another example, the interface device(s) 420 may receive and decode electrical and/or electromagnetic signals that are transmitted by the other device(s) 424. To illustrate, the other device(s) 424 may include sensor(s) 112 and the control devices 116 when the processor(s) 402 is a component of the control system 108. The electrical and/or electromagnetic signals can be transmitted wirelessly (e.g., via propagation through free space), via one or more wires, cables, optical fibers, or via a combination of wired and wireless transmission.

The computer system 400 also includes the one or more memory devices 440. The memory device(s) 440 include any suitable computer-readable storage device depending on, for example, whether data access needs to be bi-directional or unidirectional, speed of data access required, memory capacity required, other factors related to data access, or any combination thereof. Generally, the memory device(s) 440 includes some combination of volatile memory devices and non-volatile memory devices, though in some implementations, only one or the other may be present. Examples of volatile memory devices and circuits include registers, caches, latches, many types of random-access memory (RAM), such as dynamic random-access memory (DRAM), etc. Examples of non-volatile memory devices and circuits include hard disks, optical disks, flash memory, and certain types of RAM, such as resistive random-access memory (ReRAM). Other examples of both volatile and non-volatile memory devices can be used as well, or in the alternative, so long as such memory devices store information in a physical, tangible medium. Thus, the memory device(s) 440 includes circuits and structures and is not merely signals or other transitory phenomena (e.g., is non-transitory media, such as non-transitory computer-readable storage device(s) and non-transitory computer-readable storage media).

In the example illustrated in FIG. 4, the memory device(s) 440 store instructions 444 that are executable by the processor(s) 402 to perform various operations and functions. The instructions 444 include instructions to enable the various components and subsystems of the computer system 400 to operate, interact with one another, and interact with a user, such as a basic input/output system (BIOS) 446 and an operating system (OS) 448. Additionally, the instructions 444 include one or more applications 450, scripts, or other program code to enable the processor(s) 402 to perform the operations described herein.

For example, in FIG. 4, the instructions 444 include preprocessing instructions 452, engine instructions 454, postprocessing instructions 456, and graphical user interface (GUI) engine instructions 462. The preprocessing instructions 452 are executable by the processor(s) 402 to initiate, perform, or control any of the operations of the preprocessors 132, 148 described with reference to FIGS. 1-3. The engine instructions 454, in conjunction with parameters 442 (e.g., hyperparameters and parameters of regression models) are executable by the processor(s) 402 to initiate, perform, or control any of the operations of the controller 134, virtual sensors 106, or regression models 154 described with reference to FIGS. 1-3. The postprocessing instructions 456 are executable by the processor(s) 402 to initiate, perform, or control any of the operations of the postprocessor 152 described with reference to FIGS. 1-3. The GUI engine instructions 462 are executable by the processor(s) 402 to generate a GUI 432.

Particular aspects of the disclosure are highlighted in the following Examples:

According to Example 1, a device includes an interface configured to receive first sensor data from multiple first sensors associated with a monitored system; and one or more processors configured to provide first input data to a plurality of regression models of a first virtual sensor corresponding to a particular sensor of the monitored system, wherein the first input data is based on the first sensor data; obtain, from the plurality of regression models, output data based on the first input data, wherein the output data from each regression model of the plurality of regression models represents an estimated sensor reading of the particular sensor; and determine a simulated sensor reading for the particular sensor based on the output data.

Example 2 includes the device of Example 1, wherein the one or more processors are further configured to determine, based on the output data and historical sensor data, a confidence estimate associated with the simulated sensor reading.

Example 3 includes the device of Example 2, wherein the confidence estimate is based on a range of values of the output data and a mean of noise-filtered historical data used to train the first virtual sensor.

Example 4 includes the device of Example 2 or Example 3, wherein the one or more processors are further configured to generate an alert based on a mean of plurality of confidence estimates being less than a confidence estimate threshold.

Example 5 includes the device of any of Example 1 to 4, wherein the first input data excludes data associated with the particular sensor.

Example 6 includes the device of any of Example 1 to 5, wherein the plurality of regression models includes one or more extreme gradient boosting (XGB) regression models, one or more linear regression models, one or more ridge regression models, one or more neural network regression models, one or more random forest regression models, or combinations thereof.

Example 7 includes the device of any of Examples 1 to 6, wherein at least two of the regression models of the plurality of regression models are trained using different sets of training data.

Example 8 includes the device of any of Example 1 to 7, wherein the particular sensor is a failed sensor.

Example 9 includes the device of any of Example 1 to 8, wherein the particular sensor is an operational sensor, and wherein the simulated sensor reading is used to determine an error metric associated with the first virtual sensor based on comparisons of a plurality of simulated sensor readings including the simulated sensor reading to corresponding actual sensor readings determined from the first sensor data for the particular sensor.

Example 10 includes the device of any of Example 1 to 9, wherein the first sensors correspond to well head sensors, well bore sensors, or both, of a subsea well.

According to Example 11, a method includes generating, by one or more processors, input data from first sensor data, the first sensor data from multiple sensors associated with a monitored system; providing, by the one or more processors, the input data to a plurality of regression models of a first virtual sensor corresponding to a particular sensor of the monitored system; obtaining, by the one or more processors from the plurality of regression models, output data based on the input data, wherein the output data from each regression model of the plurality of regression models represents an estimated sensor reading of the particular sensor; and determining, by the one or more processors, a simulated sensor reading for the particular sensor based on the output data.

Example 12 includes the method of Example 11, further comprising providing the simulated sensor reading to a controller.

Example 13 includes the method of Example 12, further comprising sending a control signal generated by the controller based on the simulated sensor reading for the particular sensor to a control device of the monitored system.

Example 14 includes the method of any of Examples 11 to 13, further includes generating, by the one or more processors, second input data for a second virtual sensor corresponding to a second particular sensor of the monitored system, wherein the second input data is based on the first sensor data, the simulated sensor reading, or both; and providing, by the one or more processors, the second input data to the second virtual sensor to generate a simulated sensor reading for the second particular sensor.

Example 15 includes the method of any of Examples 11 to 14, wherein the particular sensor is an operational sensor, and further includes determining, by the one or more processors, an error metric associated with the first virtual sensor based on comparisons of a plurality of simulated sensor readings to corresponding actual sensor readings determined from the first sensor data for the particular sensor; and sending a request to a virtual sensor generator to update the first virtual sensor based on the error metric exceeding an error metric threshold.

Example 16 includes the method of any of Examples 11 to 15, wherein the particular sensor is a failed sensor, and further includes determining, by the one or more processors for a set of recent historical sensor data, an error metric for the first virtual sensor for the set of recent historical sensor data; and sending a request to a virtual sensor generator to update the first virtual sensor based on the error metric exceeding an error metric threshold.

Example 17 includes the method of Example 16, and further includes providing an alert to one or more operators of the monitored system to indicate that the error metric exceeds the error metric threshold.

Example 18 includes the method of any of Examples 11 to 17, wherein the particular sensor is a failed sensor, and further includes determining, by the one or more processors, that the particular sensor is scheduled to be updated; and send output to indicate possible degradation of accuracy of the simulated sensor readings generated by the first virtual sensor.

According to Example 19, a non-transitory computer-readable medium comprising instructions that are executable by one or more processors to cause the one or more processors to generate input data from first sensor data, the first sensor data from multiple first sensors associated with a monitored system; provide the input data to a plurality of regression models of a first virtual sensor corresponding to a particular sensor of the monitored system; obtain, from the plurality of regression models, output data based on the input data, wherein the output data from each regression model of the plurality of regression models represents an estimated sensor reading of the particular sensor; and determine a simulated sensor reading for the particular sensor based on the output data.

Example 20 includes the non-transitory computer-readable medium of Example 19, wherein the instructions are further executable by the one or more processors to cause a control signal generated based on the simulated sensor reading to be sent to a control device of the monitored system.

The systems and methods illustrated herein may be described in terms of functional block components, screen shots, optional selections and various processing steps. It should be appreciated that such functional blocks may be realized by any number of hardware and/or software components configured to perform the specified functions. For example, the system may employ various integrated circuit components, e.g., memory elements, processing elements, logic elements, look-up tables, and the like, which may carry out a variety of functions under the control of one or more microprocessors or other control devices. Similarly, the software elements of the system may be implemented with any programming or scripting language such as C, C++, C#, Java, JavaScript, VBScript, Macromedia Cold Fusion, COBOL, Microsoft Active Server Pages, assembly, PERL, PHP, AWK, Python, Visual Basic, SQL Stored Procedures, PL/SQL, any UNIX shell script, and extensible markup language (XML) with the various algorithms being implemented with any combination of data structures, objects, processes, routines or other programming elements. Further, it should be noted that the system may employ any number of techniques for data transmission, signaling, data processing, network control, and the like.

The systems and methods of the present disclosure may be embodied as a customization of an existing system, an add-on product, a processing apparatus executing upgraded software, a standalone system, a distributed system, a method, a data processing system, a device for data processing, and/or a computer program product. Accordingly, any portion of the system or a module or a decision model may take the form of a processing apparatus executing code, an internet based (e.g., cloud computing) embodiment, an entirely hardware embodiment, or an embodiment combining aspects of the internet, software, and hardware. Furthermore, the system may take the form of a computer program product on a computer-readable storage medium or device having computer-readable program code (e.g., instructions) embodied or stored in the storage medium or device. Any suitable computer-readable storage medium or device may be utilized, including hard disks, CD-ROM, optical storage devices, magnetic storage devices, and/or other storage media. As used herein, a “computer-readable storage medium” or “computer-readable storage device” is not a signal.

Systems and methods may be described herein with reference to screen shots, block diagrams and flowchart illustrations of methods, apparatuses (e.g., systems), and computer media according to various aspects. It will be understood that each functional block of a block diagram and flowchart illustration, and combinations of functional blocks in block diagrams and flowchart illustrations, respectively, can be implemented by computer program instructions.

Computer program instructions may be loaded onto a computer or other programmable data processing apparatus to produce a machine, such that the instructions that execute on the computer or other programmable data processing apparatus create means for implementing the functions specified in the flowchart block or blocks. These computer program instructions may also be stored in a computer-readable memory or device that can direct a computer or other programmable data processing apparatus to function in a particular manner, such that the instructions stored in the computer-readable memory produce an article of manufacture including instruction means which implement the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions specified in the flowchart block or blocks.

Accordingly, functional blocks of the block diagrams and flowchart illustrations support combinations of means for performing the specified functions, combinations of steps for performing the specified functions, and program instruction means for performing the specified functions. It will also be understood that each functional block of the block diagrams and flowchart illustrations, and combinations of functional blocks in the block diagrams and flowchart illustrations, can be implemented by either special purpose hardware-based computer systems which perform the specified functions or steps, or suitable combinations of special purpose hardware and computer instructions.

Although the disclosure may include one or more methods, it is contemplated that it may be embodied as computer program instructions on a tangible computer-readable medium, such as a magnetic or optical memory or a magnetic or optical disk/disc. All structural, chemical, and functional equivalents to the elements of the above-described exemplary embodiments that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

Changes and modifications may be made to the disclosed embodiments without departing from the scope of the present disclosure. These and other changes or modifications are intended to be included within the scope of the present disclosure, as expressed in the following claims.

What is claimed is:

1. A device comprising:
an interface configured to receive first sensor data from multiple first sensors associated with a monitored system; and
one or more processors configured to:
provide first input data to a plurality of regression models of a first virtual sensor corresponding to a particular sensor of the monitored system, wherein the first input data is based on the first sensor data;
obtain, from the plurality of regression models, output data based on the first input data, wherein the output data from each regression model of the plurality of regression models represents an estimated sensor reading of the particular sensor; and
determine a simulated sensor reading for the particular sensor based on the output data.

2. The device of claim 1, wherein the one or more processors are further configured to determine, based on the output data and historical sensor data, a confidence estimate associated with the simulated sensor reading.

3. The device of claim 2, wherein the confidence estimate is based on a range of values of the output data and a mean of noise-filtered historical data used to train the first virtual sensor.

4. The device of claim 2, wherein the one or more processors are further configured to generate an alert based on a mean of a plurality of confidence estimates being less than a confidence estimate threshold.

5. The device of claim 1, wherein the first input data excludes data associated with the particular sensor.

6. The device of claim 1, wherein the plurality of regression models includes one or more extreme gradient boosting (XGB) regression models, one or more linear regression models, one or more ridge regression models, one or more neural network regression models, one or more random forest regression models, or combinations thereof.

7. The device of claim 1, wherein at least two of the regression models of the plurality of regression models are trained using different sets of training data.

8. The device of claim 1, wherein the particular sensor is a failed sensor.

9. The device of claim 1, wherein the particular sensor is an operational sensor, and wherein the simulated sensor reading is used to determine an error metric associated with the first virtual sensor based on comparisons of a plurality of simulated sensor readings including the simulated sensor reading to corresponding actual sensor readings determined from the first sensor data for the particular sensor.

10. The device of claim 1, wherein the first sensors correspond to well head sensors, well bore sensors, or both, of a subsea oil well.

11. A method comprising:
generating, by one or more processors, input data from first sensor data, the first sensor data from multiple sensors associated with a monitored system;
providing, by the one or more processors, the input data to a plurality of regression models of a first virtual sensor corresponding to a particular sensor of the monitored system;
obtaining, by the one or more processors from the plurality of regression models, output data based on the input data, wherein the output data from each regression model of the plurality of regression models represents an estimated sensor reading of the particular sensor; and
determining, by the one or more processors, a simulated sensor reading for the particular sensor based on the output data.

12. The method of claim 11, further comprising providing the simulated sensor reading to a controller.

13. The method of claim 12, further comprising sending a control signal generated by the controller based on the simulated sensor reading for the particular sensor to a control device of the monitored system.

14. The method of claim 11, further comprising:
generating, by the one or more processors, second input data for a second virtual sensor corresponding to a second particular sensor of the monitored system, wherein the second input data is based on the first sensor data, the simulated sensor reading, or both; and
providing, by the one or more processors, the second input data to the second virtual sensor to generate a simulated sensor reading for the second particular sensor.

15. The method of claim 11, wherein the particular sensor is an operational sensor, and further comprising:
determining, by the one or more processors, an error metric associated with the first virtual sensor based on comparisons of a plurality of simulated sensor readings to corresponding actual sensor readings determined from the first sensor data for the particular sensor; and
sending a request to a virtual sensor generator to update the first virtual sensor based on the error metric exceeding an error metric threshold.

16. The method of claim 11, wherein the particular sensor is a failed sensor, and further comprising:
determining, by the one or more processors for a set of recent historical sensor data, an error metric for the first virtual sensor for the set of recent historical sensor data; and
sending a request to a virtual sensor generator to update the first virtual sensor based on the error metric exceeding an error metric threshold.

17. The method of claim 16, further comprising providing an alert to one or more operators of the monitored system to indicate that the error metric exceeds the error metric threshold.

18. The method of claim 11, wherein the particular sensor is a failed sensor, and further comprising:
determining, by the one or more processors, that the particular sensor is scheduled to be updated; and
send output to indicate possible degradation of accuracy of the simulated sensor readings generated by the first virtual sensor.

19. A non-transitory computer-readable medium comprising instructions that are executable by one or more processors to cause the one or more processors to:
generate input data from first sensor data, the first sensor data from multiple first sensors associated with a monitored system;
provide the input data to a plurality of regression models of a first virtual sensor corresponding to a particular sensor of the monitored system;
obtain, from the plurality of regression models, output data based on the input data, wherein the output data from each regression model of the plurality of regression models represents an estimated sensor reading of the particular sensor; and
determine a simulated sensor reading for the particular sensor based on the output data.

20. The non-transitory computer-readable medium of claim 19, wherein the instructions are further executable by the one or more processors to cause a control signal generated based on the simulated sensor reading to be sent to a control device of the monitored system.
